(19) United States
(12) Patent Application Publication
(10) Pub. No.: US 2014/0077292 A1
(43) Pub. Date: Mar. 20, 2014

(54) SEMICONDUCTOR DEVICE AND MANUFACTURING METHOD THEREOF

(71) Applicant: KABUSHIKI KAISHA TOSHIBA, Tokyo (JP)

(72) Inventors: Takuya NOGAMI, Nonoichi-shi (JP); Hideki OKUMURA, Nonoichi-shi (JP); Takahiro KAWANO, Yokohama-shi (JP)

(21) Appl. No.: 13/849,438

(22) Filed: Mar. 22, 2013

(30) Foreign Application Priority Data
Sep. 20, 2012 (JP) 2012-207556

(51) Int. Cl. H01L 29/78; H01L 29/66

(52) U.S. Cl. CPC H01L 29/7813; H01L 29/66734
USPC 257/330; 438/270

(57) ABSTRACT

According to one embodiment, a semiconductor device includes a semiconductor substrate including a drain layer of a first conductivity type and a base layer of a second conductivity type provided on the drain layer, a gate electrode including a first portion formed in the semiconductor substrate, a gate insulating layer provided between the gate electrode and the semiconductor substrate, an upper insulating layer formed on the gate electrode, a source layer of the first conductivity type that is provided on a sidewall of the upper insulating layer and whose width increases towards the base layer, and a source electrode provided on the source layer.

### CROSS-REFERENCE TO RELATED APPLICATIONS

This application is based upon and claims the benefit of priority from Japanese Patent Application No. 2012-207556, filed Sep. 20, 2012, the entire contents of which are incorporated herein by reference.

### FIELD

Embodiments described herein relate generally to a semiconductor device and a manufacturing method thereof.

### BACKGROUND

In a MOSFET having a trench gate for a power device, miniaturization thereof is increasingly required. However, it cannot necessarily be said that the structure and manufacturing method for achieving the miniaturization are provided.

Therefore, in this type of MOSFET, the structure and manufacturing method for achieving the miniaturization are desired.

### BRIEF DESCRIPTION OF THE DRAWINGS

FIG. 1 is a cross-sectional view schematically showing the structure of a semiconductor device according to a first embodiment.

FIG. 2 is a cross-sectional view schematically showing a manufacturing method of the semiconductor device according to the first embodiment.

FIG. 3 is a cross-sectional view schematically showing a manufacturing method of the semiconductor device according to the first embodiment.

FIG. 4 is a cross-sectional view schematically showing a manufacturing method of the semiconductor device according to the first embodiment.

FIG. 5 is a cross-sectional view schematically showing a manufacturing method of the semiconductor device according to the first embodiment.

FIG. 6 is a cross-sectional view schematically showing a manufacturing method of the semiconductor device according to the first embodiment.

FIG. 7 is a cross-sectional view schematically showing a manufacturing method of the semiconductor device according to the first embodiment.

FIG. 8 is a cross-sectional view schematically showing a manufacturing method of the semiconductor device according to the first embodiment.

FIG. 9 is a cross-sectional view schematically showing a manufacturing method of the semiconductor device according to the first embodiment.

FIG. 10 is a cross-sectional view schematically showing a manufacturing method of the semiconductor device according to the first embodiment.

FIG. 11 is a cross-sectional view schematically showing a manufacturing method of a semiconductor device according to a second embodiment.

FIG. 12 is a cross-sectional view schematically showing a manufacturing method of the semiconductor device according to the second embodiment.

FIG. 13 is a cross-sectional view schematically showing a manufacturing method of the semiconductor device according to the second embodiment.

FIG. 14 is a cross-sectional view schematically showing a manufacturing method of the semiconductor device according to the second embodiment.

FIG. 15 is a cross-sectional view schematically showing a manufacturing method of the semiconductor device according to the second embodiment.

### DETAILED DESCRIPTION

In general, according to one embodiment, a semiconductor device includes: a semiconductor substrate including a drain layer of a first conductivity type and a base layer of a second conductivity type provided on the drain layer; a gate electrode including a first portion formed in the semiconductor substrate; a gate insulating layer provided between the gate electrode and the semiconductor substrate; an upper insulating layer formed on the gate electrode; a source layer of the first conductivity type that is provided on a sidewall of the upper insulating layer and whose width increases towards the base layer; and a source electrode provided on the source layer.

Embodiments are explained below with reference to the drawings.

### Embodiment 1

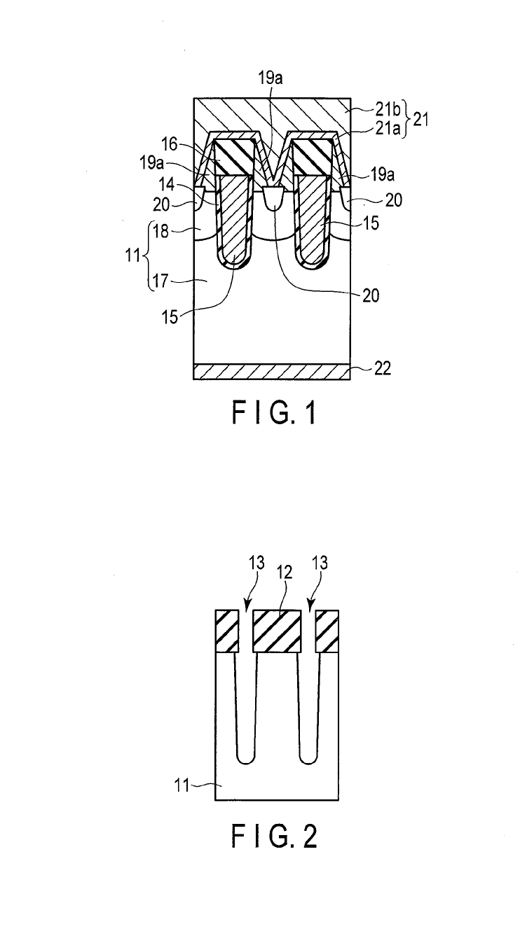

FIG. 1 is a cross-sectional view schematically showing the structure of a semiconductor device (a MOSFET having a trench gate for a power device) according to a first embodiment.

A semiconductor substrate 11 is formed of silicon and includes an n-type (first conductivity type) drain layer 17 and p-type (second conductivity type) base layers 18 provided on the drain layer 17. A drain electrode 22 is connected to the drain layer 17. Although not shown in the drawing, the drain layer 17 includes a layer (n layer) having relatively low n-type impurity concentration and formed on the base layer 18 side and a layer (n⁺ layer) having relatively high n-type impurity concentration and formed on the drain electrode 22 side.

Gate electrodes 15 are formed of polysilicon and each include a first portion formed in the semiconductor substrate 11 and a second portion projecting from the semiconductor substrate 11 (projecting from the base layer 18). Gate insulating films 14 formed of silicon oxide films are provided between the gate electrodes 15 and the semiconductor substrate 11. Upper insulating layers 16 formed of silicon oxide films are provided on the gate electrodes 15.

Source layers 19a are provided on the sidewalls of the upper insulating films 16 and the sidewalls of the second portions of the gate electrodes 15. The bottom portion of the source layer 19a is formed in contact with the base layer 18. The source layer 19a is formed of silicon having phosphorus (P) doped therein as n-type (first conductivity type) impurity. The width of the source layer 19a increases towards the base layer 18, that is, the width increases towards the bottom portion thereof. In other words, the source layer 19a is formed in a tapered form. Further, the n-type impurity concentration of the source layer 19a is gradually lowered towards the base layer 18.

A source electrode 21 formed of a stack film of a barrier metal layer 21a and aluminum layer 21b is provided on the source layers 19a. The source electrode 21 fills a space between the adjacent source layers 19a. Also, it is possible to use a tungsten layer instead of the aluminum layer 21b. Further, instead of the aluminum layer 21b, a stack structure of a tungsten layer and aluminum layer can be used.

High-impurity concentration layers 20 having p-type impurity (second conductivity type impurity) concentration higher than that of the base layer are provided separately from the gate electrodes 15 and gate insulating films 14 in a surface region of the base layer 18. Each high-impurity concentration layer 20 is formed in contact with the source layer 19a and the edge of the high-impurity concentration layer 20 is substantially aligned with the edge of the source layer 19a.

In the semiconductor device of the present embodiment described above, each source layer 19a has a tapered form whose width increases towards the base layer 18. Therefore, the source electrode 21 can easily fill the space between the adjacent source layers 19a. As a result, even if the distance between the adjacent transistors (the distance between the adjacent source layers 19a) becomes shorter, the connection (contact) between the source electrode 21 and the source layer 19a can be stably made in a large contact area. Therefore, in the semiconductor device of the present embodiment, a miniaturized semiconductor device in which the source electrode 21 and the source layer 19a are stably connected to each other can be obtained.

Further, in the embodiment described above, since the source layers 19a are provided on the sidewalls of the upper insulating layers 16 and the sidewalls of the second portion of the gate electrodes 15, it is unnecessary to align the source layers 19a with the gate electrodes 15. Therefore, a miniaturized semiconductor device in which the source layers 19a can be stably matched with the gate electrodes 15 can be obtained.

Next, a manufacturing method of a semiconductor device (a MOSFET having a trench gate for a power device) according to the present embodiment is explained. FIG. 2 to FIG. 10 are cross-sectional views schematically showing a manufacturing method of the semiconductor device according to the present embodiment. In FIG. 2 to FIG. 10, the lower half portion of the drain layer 17 and the drain electrode 22 shown in FIG. 1 are omitted.

First, as shown in FIG. 2, a mask layer 12 is formed on an n-type semiconductor substrate (silicon substrate) 11. Trenches 13 are formed in the semiconductor substrate 11 by RIE (reactive ion etching) with the mask layer 12 used as a mask.

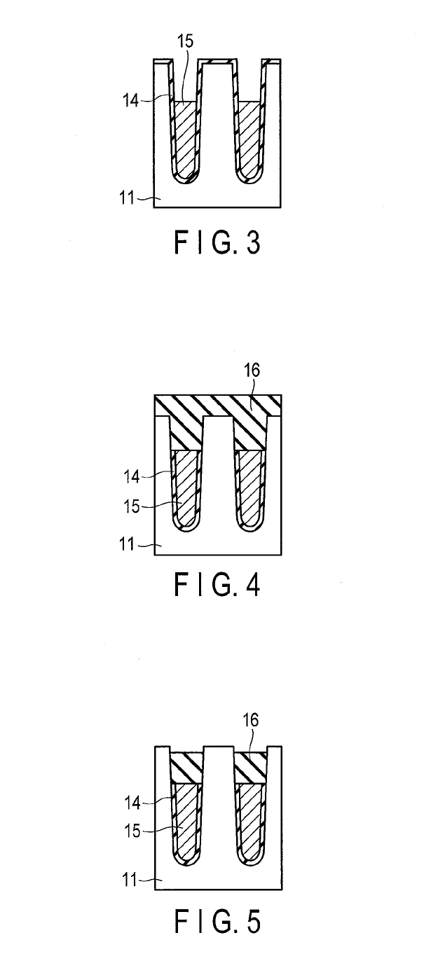

Next, as shown in FIG. 3, a gate insulating film 14 is formed on the inner walls of the trenches 13 by thermal oxidation. Then, a polysilicon film 15 is formed as a gate electrode film on the entire surface including the inner portions of the trenches 13. The polysilicon film 15 is etched back to set the upper surface of the polysilicon film 15 lower than the upper surface of the semiconductor substrate 11. Thus, the gate electrodes 15 each formed of the polysilicon film are obtained.

Next, as shown in FIG. 4, a silicon oxide film 16 is formed as an insulating film on the entire surface including the inner portions of the trenches 13. That is, the silicon oxide film 16 is formed on the gate electrodes 15 and semiconductor substrate 11.

Next, as shown in FIG. 5, part of the silicon oxide film 16 is removed by etch-back to reduce the thickness of the silicon oxide film 16. As a result, silicon oxide films as the upper insulating films 16 are left behind in the trenches 13.

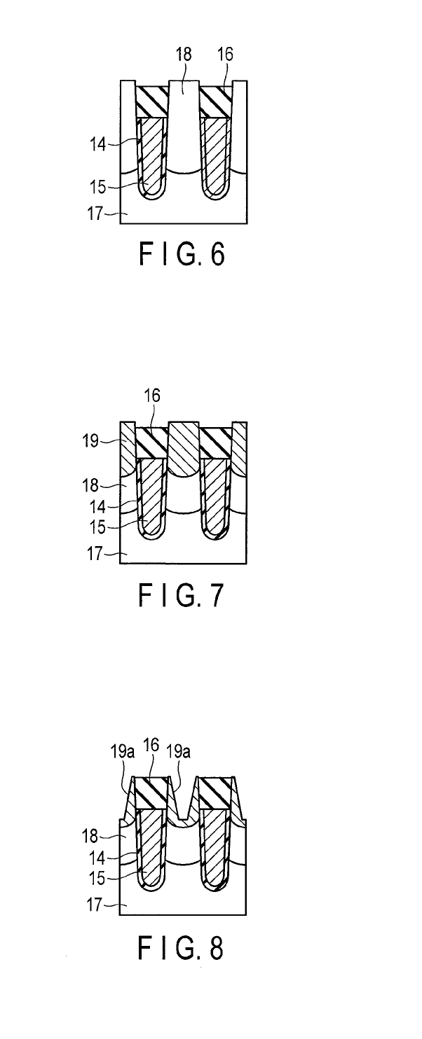

Next, as shown in FIG. 6, p-type impurity is doped into the upper portion of the semiconductor substrate 11 by ion-implantation. As a result, the upper portion of the semiconductor substrate 11 is inverted from the n type to the p type.

As described above, as shown in FIG. 6, the structure including a semiconductor substrate that includes a first semiconductor layer 17 of an n type (first conductivity type) and a second semiconductor layer 18 of a p type (second conductivity type) provided on the first semiconductor layer 17, gate electrodes 15 provided in the semiconductor substrate, gate insulating films 14 provided between the gate electrodes 15 and the semiconductor substrate 11, and upper insulating layers 16 provided on the gate electrodes 15 is obtained.

Next, as shown in FIG. 7, n-type (first conductivity type) impurity is doped into the upper portion of the second semiconductor layers 18 to form inversion layers 19 that are each inverted from the p type to the n type on the upper portion of the second semiconductor layers 18. The lower portion of the second semiconductor layer is left behind as the p-type base layer 18. The process of doping n-type impurity into the upper portions of the second semiconductor layers 18 is performed by vapor-phase diffusion of phosphorus (P). Since the process of doping n-type impurity is performed by vapor-phase diffusion, the n-type impurity concentration of the inversion layer 19 is lowered towards the base layer 18.

Next, as shown in FIG. 8, the inversion layer 19 is subjected to anisotropic etching. Specifically, anisotropic etching is performed by RIE using etching gas such as HBr or NF₃. As a result, tapered-form n-type source layers 19a whose widths increase towards the base layers 18 are formed on the sidewalls of the upper insulating layers 16 and the sidewalls of portions of the gate electrodes 15 that project from the base layers 18. The tapered-form n-type source layers 19a can be formed by adequately setting the condition of anisotropic etching. In FIG. 8, an n-type layer is left behind between the adjacent source layers 19a, but an n-type layer between the adjacent source layers 19a may be completely removed by anisotropic etching.

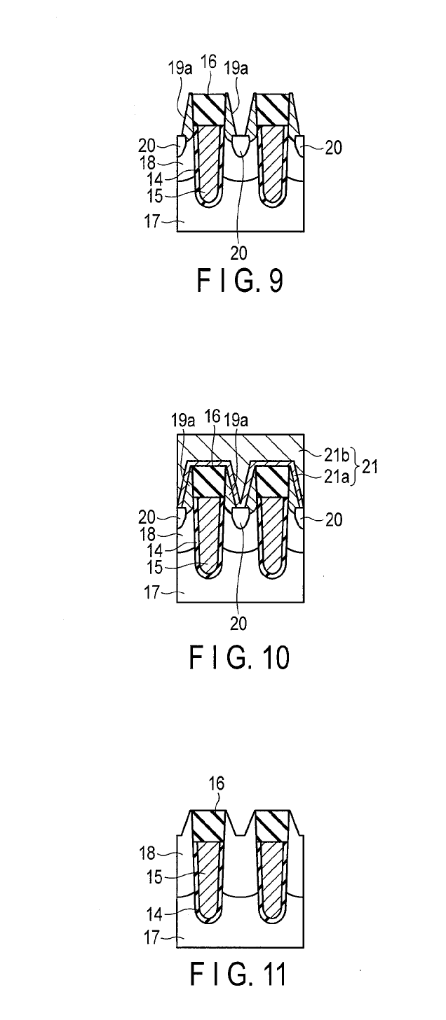

Next, as shown in FIG. 9, p-type impurity is doped into the surface regions of the base layers 18 with the source layers 19a used as a mask. Specifically, p-type impurity is doped into the surface regions of the base layers 18 by ion implantation. At this time, the ion-implantation condition of p-type impurity is adjusted to set the concentration of p-type impurity doped into the base layer 18 lower than the n-type impurity concentration of the source layer 19a. Further, as shown in FIG. 8, the ion-implantation condition of p-type impurity is adjusted to set the concentration thereof higher than the n-type impurity concentration of an n-type layer when the n-type layer is left behind between the adjacent source layers 19a. Thus, high-impurity concentration layers 20 having the p-type impurity concentration higher than that of the base layer 18 are formed separately from the gate electrodes 15 and gate insulating films 14.

Next, as shown in FIG. 10, a source electrode 21 is formed on the source layers 19a, high-impurity concentration layers 20 and upper insulating layers 16. A stack film of a barrier metal layer 21a and aluminum layer 21b is used as the source electrode 21. In this case, a tungsten layer may be used instead of the aluminum layer 21b. Further, a stack structure of a tungsten layer and aluminum layer may be used instead of the aluminum layer 21b.

As described above, a semiconductor device as shown in FIG. 10 and FIG. 1 is formed. The drain electrode 22 shown in FIG. 1 is formed at an adequate stage of FIG. 2 to FIG. 10.

Thus, with the manufacturing method described above, the tapered-form source layers 19a whose widths increase towards the base layers 18 are formed on the sidewalls of the upper insulating layers 16 and the projecting portions (second portions) of the gate electrodes by performing anisotropic etching. Therefore, the source electrode 21 can be formed to easily fill each space between the adjacent source layers 19a. As a result, even if the distance between the adjacent transistors (the distance between the adjacent source layers 19a) becomes short, the connection (contact) between the source electrode 21 and the source layers 19a can be stably attained in a large contact area. Therefore, a miniaturized semiconductor device in which the source electrode 21 is stably connected to the source layers 19a can be obtained.

Further, with the manufacturing method described above, since the source layers 19a are formed on the sidewalls of the upper insulating layers 16 and the sidewalls of the projecting portions of the gate electrodes 15 by anisotropic etching, it becomes unnecessary to align the source layers 19a with the gate electrodes 15. Therefore, the source layers 19a can stably be matched with the gate electrodes 15 and a miniaturized semiconductor device can be obtained.

Further, with the manufacturing method described above, n-type impurity is doped by vapor-phase diffusion when n-type impurity is doped into the upper portion of the second semiconductor layer 18 to form the inversion layer 19. It is possible to dope n-type impurity with high concentration by doping n-type impurity by vapor-phase diffusion. Therefore, the inversion layer 19 with high-concentration n-type impurity can be formed. As a result, the high-concentration source layers 19a having high-concentration n-type impurity can be formed and the contact resistance between the source layers 19a and the source electrode 21 can be reduced.

Further, since n-type impurity is doped by vapor-phase diffusion, the n-type impurity concentration of the inversion layer 19 is lowered towards the base layer 18. That is, the n-type impurity concentration in the source layers 19a is lowered towards the base layer. Therefore, even if an n-type layer is left behind between the adjacent source layers 19a when the high-impurity concentration layers 20 are formed, the n-type impurity concentration of the n-type layer is low. As a result, the p-type high-impurity concentration layers 20 can stably be formed by doping p-type impurity.

Further, since p-type impurity is doped into the surface regions of the base layers 18 with the source layers 19a used as a mask when the high-impurity concentration layers 20 are formed, the high-impurity concentration layers 20 can be formed in a self-alignment fashion with respect to the source layers 19a. Therefore, the distance between adjacent transistors can be reduced and a miniaturized semiconductor device can be obtained.

### Embodiment 2

Next, a second embodiment is explained. The basic configuration is the same as the configuration of FIG. 1 in the first embodiment. Further, the basic manufacturing method is similar to the manufacturing method of the first embodiment. Therefore, the explanation for the same items as those explained in the first embodiment is omitted.

FIG. 11 to FIG. 15 are cross-sectional views schematically showing a manufacturing method of a semiconductor device according to the present embodiment. In FIG. 11 to FIG. 15, the lower half portion of the drain layer 17 and the drain electrode 22 shown in FIG. 1 are omitted.

First, the same process as the process from FIG. 2 to FIG. 6 of the first embodiment is performed and the structure shown in FIG. 6 is formed.

Next, as shown in FIG. 11, a second semiconductor layer 18 is subjected to anisotropic etching to form sidewall portions whose widths increase from top to bottom (towards base layers that will be described later) on the sidewalls of upper insulating layers 16. Specifically, anisotropic etching is performed by RIE using etching gas such as HBr or NF₃. As a result, tapered-form sidewall portions whose widths increase from top to bottom (towards base layers that will be described later) are formed on the sidewalls of the upper insulating layers 16. The tapered-form sidewall portions can be formed by adequately setting the condition of anisotropic etching.

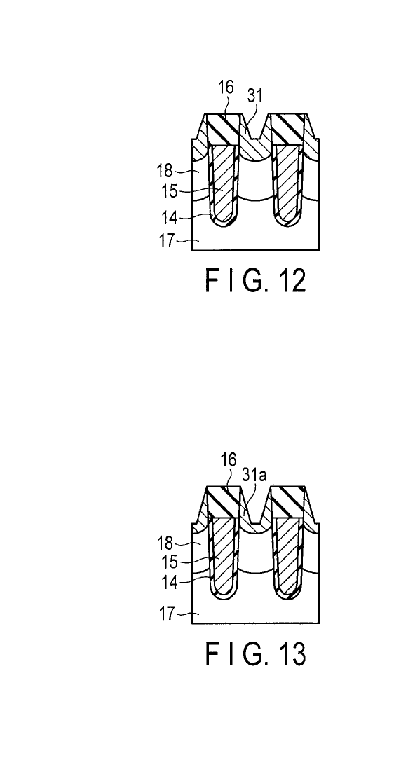

Next, as shown in FIG. 12, n-type (first conductivity type) impurity is doped into the upper portions of the second semiconductor layers 18 including the sidewall portions described above. As a result, an inversion layer 31 that is inverted to an n type is formed on the upper portions of the second semiconductor layers 18. The lower portion of the second semiconductor layer is left behind as a p-type base layer 18. The process of doping n-type impurity into the upper portions of the second semiconductor layer is performed by vapor-phase diffusion of phosphorus (P). Since the process of doping n-type impurity is performed by vapor-phase diffusion, the n-type impurity concentration in the inversion layer 31 becomes lower towards the base layer 18.

Next, as shown in FIG. 13, the inversion layer 31 is etched back. As a result, the thickness of the inversion layer 31 is reduced to form source layers 31a. That is, the n-type source layers 31a of the tapered form whose widths increase towards the base layer 18 are formed on the sidewalls of the upper insulating layers 16 and the sidewalls of portions of the gate electrodes 15 that project from the base layers 18.

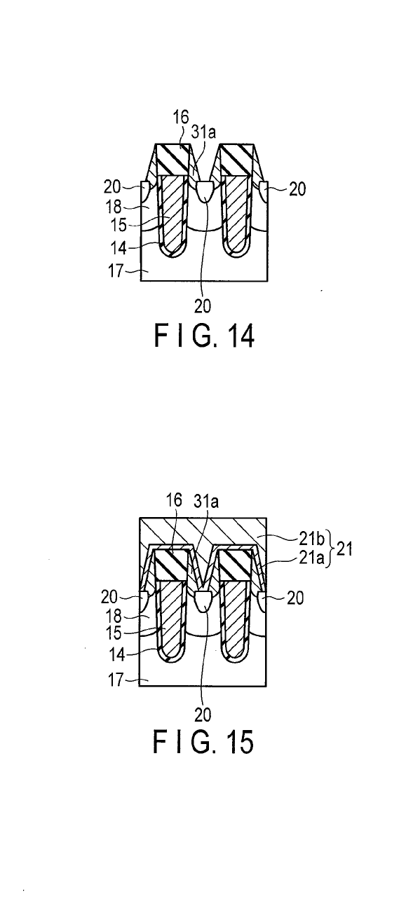

Next, as shown in FIG. 14, p-type impurity is doped into the surface regions of the base layers 18 with the source layers 31a used as a mask. Specifically, p-type impurity is doped into the surface region of the base layer 18 by ion implantation. At this time, the ion-implantation condition of p-type impurity is adjusted to set the concentration of p-type impurity doped into the base layer 18 lower than the n-type impurity concentration of the source layer 31a. Further, as shown in FIG. 13, when an n-type layer is left behind between the adjacent source layers 31a, the ion-implantation condition of p-type impurity is adjusted to set the concentration thereof higher than the n-type impurity concentration of the n-type layer. Thus, high-impurity concentration layers 20 having the p-type impurity concentration higher than that of the base layer 18 are formed separately from the gate electrodes 15 and gate insulating films 14.

Next, as shown in FIG. 15, a source electrode 21 is formed on the source layers 31a, high-impurity concentration layers 20 and upper insulating layers 16. A stack film of a barrier metal layer 21a and aluminum layer 21b is used as the source electrode 21. In this case, a tungsten layer may be used instead of the aluminum layer 21b. Further, a stack structure of a tungsten layer and aluminum layer may be used instead of the aluminum layer 21b.

As described above, a semiconductor device as shown in FIG. 15 and FIG. 1 is formed. The drain electrode 22 shown in FIG. 1 is formed at an adequate stage of FIG. 2 to FIG. 6 or FIG. 11 to FIG. 15.

With the manufacturing method described above, the same effect as the effect described in the first embodiment can be obtained.

The first and second embodiments are explained above, but the first and second embodiments can be variously modified.

In the first embodiment, anisotropic etching is performed after doping n-type (first conductivity type) impurity to form the inversion layer 19. Further, in the second embodiment, n-type (first conductivity type) impurity is doped to form the inversion layer 31 after anisotropic etching is performed. Thus, the order of the process of doping n-type (first conductivity type) impurity and the anisotropic etching process is not particularly limited. Generally speaking, it is sufficient if the process is performed to form the n-type (first conductivity type) source layers 19a (or 31a) whose widths increase towards the base layer on the sidewalls of the upper insulating layers 16 by performing doping of n-type (first conductivity type) impurity into and anisotropic-etching with respect to the upper portions of the second semiconductor layer 18 and leave the lower portion of the second semiconductor layer 18 as the p-type (second conductivity type) base layer 18.

Further, the semiconductor device described above (a MOSFET having a trench gate for a power device) can also be applied to a so-called field plate FET.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate including a drain layer of a first conductivity type and a base layer of a second conductivity type provided on the drain layer;
a gate electrode including a first portion formed in the semiconductor substrate;
a gate insulating layer provided between the gate electrode and the semiconductor substrate;
an upper insulating layer formed on the gate electrode;
a source layer of the first conductivity type that is provided on a sidewall of the upper insulating layer and whose width increases towards the base layer; and
a source electrode provided on the source layer.

2. The device of claim 1, wherein the source layer has a first conductivity type impurity concentration that is lowered towards the base layer.

3. The device of claim 1, wherein the gate electrode further includes a second portion that projects from the semiconductor substrate.

4. The device of claim 3, wherein the source layer is further provided on a sidewall of the second portion.

5. The device of claim 1, further comprising a high-impurity concentration layer provided on a surface region of the base layer, formed separately from the gate electrode and the gate insulating film and having a second conductivity type impurity concentration higher than that of the base layer.

6. The device of claim 5, wherein the high-impurity concentration layer is formed in contact with the source layer.

7. A semiconductor device manufacturing method comprising:
forming a structure that includes a semiconductor substrate including a first semiconductor layer of a first conductivity type and a second semiconductor layer of a second conductivity type formed on the first semiconductor layer, a gate electrode provided in the semiconductor substrate, a gate insulating layer provided between the gate electrode and the semiconductor substrate, and an upper insulating layer provided on the gate electrode;
performing doping of an impurity of the first conductivity type and anisotropic-etching with respect to an upper portion of the second semiconductor layer to form a source layer of the first conductivity type on a sidewall of the upper insulating layer and leave a lower portion of the second semiconductor layer as a base layer of the second conductivity type; and
forming a source electrode on the source layer.

8. The method of claim 7, wherein the source layer has a width that increases towards the base layer.

9. The method of claim 7, wherein the anisotropic-etching is performed after the doping of the impurity of the first conductivity type.

10. The method of claim 7, wherein the doping of the impurity of the first conductivity type is performed after the anisotropic-etching.

11. The method of claim 7, wherein the doping of the impurity of the first conductivity type with respect to the upper portion of the second semiconductor layer is performed by vapor-phase diffusion.

12. The method of claim 7, wherein the source layer has a first conductivity type impurity concentration that is lowered towards the base layer.

13. The method of claim 7, wherein the gate electrode includes a portion that projects from the base layer.

14. The method of claim 13, wherein the source layer is further formed on a sidewall of the projecting portion.

15. The method of claim 7, further comprising doping an impurity of the second conductivity type into a surface region of the base layer with the source layer used as a mask to form a high-impurity concentration layer provided separately from the gate electrode and the gate insulating film and having a second conductivity type impurity concentration higher than that of the base layer.
